(19) United States
(12) Patent Application Publication
(10) Pub. No.: US 2026/0311019 A1
(43) Pub. Date: Oct. 8, 2026

(54) Preparation Method for Quantum Chip, Quantum Chip, and Quantum Computer

(71) Applicant: Tencent Technology (Shenzhen) Company Limited, Shenzhen (CN)

(72) Inventors: Kunliang BU, Shenzhen (CN); Yuan LI, Shenzhen (CN); Tianqi CAI, Shenzhen (CN); Sainan HUAI, Shenzhen (CN); Yicong ZHENG, Shenzhen (CN); Shengyu ZHANG, Shenzhen (CN)

(73) Assignee: Tencent Technology (Shenzhen) Company Limited, Shenzhen (CN)

(21) Appl. No.: 19/056,347

(22) Filed: Feb. 18, 2025

Related U.S. Application Data
(63) Continuation of application No. PCT/CN2023/097342, filed on May 31, 2023.

(30) Foreign Application Priority Data
Feb. 21, 2023 (CN) 20231071588.6

(51) Int. Cl. G06N 10/40; H10N 60/01

(52) U.S. Cl. CPC G06N 10/40; H10N 60/0688

(57) ABSTRACT

This application discloses a method for preparing a quantum chip, a quantum chip, and a quantum computer, related to the technical field of quantum chips. The method includes: spin-coating a positive photoresist on a substrate, and preparing an under bump metallization (UBM) layer and an air bridge on the substrate spin-coated with the positive photoresist, to obtain a first substrate structure; spin-coating a negative photoresist on the first substrate structure, and preparing a metal column solder joint on the first substrate structure spin-coated with the negative photoresist, to obtain a second substrate structure; and removing the positive photoresist and the negative photoresist from the second substrate structure, to obtain a quantum chip including the UBM layer, the air bridge, and the metal column solder joint. By using the method provided in exemplary embodiments of this application, preparation efficiency can be improved, and performance of the chip can be improved.

### RELATED APPLICATION

This application is a continuation of and claims the benefit of priority to PCT/CN2023/097342 filed on May 31, 2023, which is based on and claims priority to Chinese Patent Application No. 202310171588.6, filed with the China National Intellectual Property Administration on Feb. 21, 2023 and entitled “PREPARATION METHOD FOR QUANTUM CHIP, QUANTUM CHIP, AND QUANTUM COMPUTER”, both of which are incorporated herein by reference.

### FIELD OF THE TECHNOLOGY

This application relates to the technical field of quantum chips, and in particular, to a method for preparing a quantum chip, a quantum chip, and a quantum computer.

### BACKGROUND OF THE DISCLOSURE

A superconductive quantum chip transmits a microwave signal through a coplanar waveguide. However, as circuits on the quantum chip become increasingly dense, signal crosstalk between coplanar waveguides arises. To address a routing problem, a flip quantum chip can be prepared by a flip-chip bonding technology.

In the related art, a preparation process typically involves first preparing an air bridge structure in the flip quantum chip, and then preparing a metal column solder joint. During sequential preparation of the air bridge and the metal column solder joint, a photoresist needs to be spin-coated. However, in this process, it is difficult to fill up a space below a bridge body of the air bridge, and an unfilled air cavity is formed, which subsequently causes the problem of bubbling and deformation or warping of the air bridge. In addition, the presence of bubbling may result in cracking of the photoresist, and during vapor deposition of a solder joint material, a metallic filament may remain, which may alter a chip circuit.

It can be learned that the solution in the related art may not only reduce the yield of the air bridge but also compromise chip performance due to the residual metallic filament.

### SUMMARY

Exemplary embodiments of this disclosure provide a method for preparing a quantum chip, a quantum chip, and a quantum computer, to improve preparation efficiency of a flip quantum chip, and improve performance of the chip. The following technical solutions are provided.

In an aspect, exemplary embodiments of this disclosure provide a method for preparing a quantum chip, which is performed by a mask aligner and includes:
spin-coating a positive photoresist on a substrate, and preparing an under bump metallization (UBM) layer and an air bridge on the substrate based on the positive photoresist, to obtain a first substrate structure;
spin-coating a negative photoresist on the first substrate structure, and preparing a metal column solder joint based on the negative photoresist, to obtain a second substrate structure; and
removing the positive photoresist and the negative photoresist from the second substrate structure, to obtain a flip quantum chip including the UBM layer, the air bridge, and the metal column solder joint.

In another aspect, exemplary embodiments of this disclosure provide a preparation apparatus for a quantum chip, which includes:
a first preparing module, configured to spin-coat a positive photoresist on a substrate, and prepare a UBM layer and an air bridge on the substrate spin-coated with the positive photoresist, to obtain a first substrate structure, the first substrate structure having the positive photoresist subjected to photo-etching;
a second preparing module, configured to spin-coat a negative photoresist on the first substrate structure, and prepare a metal column solder joint on the first substrate structure spin-coated with the negative photoresist, to obtain a second substrate structure; and
a resist removing module, configured to remove the positive photoresist and the negative photoresist from the second substrate structure, to obtain a quantum chip including the UBM layer, the air bridge, and the metal column solder joint.

In another aspect, exemplary embodiments of this disclosure provide a mask aligner, which includes a photo-etching component, a processor, and a memory. The memory has at least one instruction stored therein, and the at least one instruction, when loaded by the processor, controls the photo-etching component to implement the preparation method for a quantum chip described in the foregoing aspect.

In another aspect, exemplary embodiments of this disclosure provide a quantum chip of which a chip structure includes a UBM layer, an air bridge, and a metal column solder joint. The quantum chip is prepared by the preparation method for a quantum chip provided in the foregoing aspect.

In another aspect, exemplary embodiments of this disclosure provide a quantum computer, which includes the quantum chip described in the foregoing aspect.

In the exemplary embodiments of this disclosure, after the UBM layer and the air bridge are prepared based on the positive photoresist, and the metal column solder joint is prepared based on the negative photoresist, the resists are removed together, and the flip quantum chip including the UBM layer, air bridge, and metal column solder joint structures is obtained. That is, by combining the positive photoresist with the negative photoresist, one-time resist removal and molding can be realized, whereby preparation efficiency can be improved. Moreover, because the positive photoresist is not removed during preparation of the metal column solder joint, that is, the positive photoresist remains below a bridge body of the air bridge, an air cavity is not formed, whereby the problem of bubbling can be avoided, and performance of the air bridge can be improved. Furthermore, if the negative photoresist cracks during preparation of the metal column solder joint based on the negative photoresist, the residual positive photoresist further protects the substrate, to prevent a metallic filament from remaining on the substrate due to cracks, and accordingly, improves the yield of a quantum chip and performance of the chip.

### BRIEF DESCRIPTION OF THE DRAWINGS

FIG. 1 is a schematic structural diagram of a flip quantum chip according to an exemplary embodiment of this disclosure.

FIG. 2 is a schematic structural diagram of an air bridge according to an exemplary embodiment of this disclosure.

FIG. 3 is a schematic diagram of an air cavity in the related art.

FIG. 4 is a flowchart of a preparation method for a quantum chip according to an exemplary embodiment of this disclosure.

FIG. 5 is a schematic structural diagram of a metal column solder joint prepared based on a negative photoresist according to an exemplary embodiment of this disclosure.

FIG. 6 is a flowchart of a preparation method for a quantum chip according to another exemplary embodiment of this disclosure.

FIG. 7 is a schematic sectional diagram of a preparation process of a quantum chip according to an exemplary embodiment of this disclosure.

FIG. 8 is a flowchart of a preparation method for a quantum chip according to another exemplary embodiment of this disclosure.

FIG. 9 is a schematic sectional diagram of a preparation process of a quantum chip according to another exemplary embodiment of this disclosure.

FIG. 10 is a flowchart of a preparation method for a quantum chip according to another exemplary embodiment of this disclosure.

FIG. 11 is a structural block diagram of a preparation apparatus for a quantum chip according to an exemplary embodiment of this disclosure.

### DESCRIPTION OF EMBODIMENTS

To make the objectives, technical solutions, and advantages of this disclosure clearer, the following further describes implementations of this disclosure in detail with reference to the accompanying drawings.

“A plurality of” mentioned herein means two or more. “And/or” describes an association relationship for describing associated objects and represents that three relationships may exist. For example, A and/or B may represent the following three cases: only A exists, both A and B exist, and only B exists. The mark “/” generally indicates an “or” relationship between the associated objects.

First, terms involved in exemplary embodiments of this disclosure are briefly introduced.
Flip quantum chip: it is formed by bonding two chips each having a metal column solder joint, and a metal column solder joint on a top chip is in contact with a metal column solder joint on a bottom chip to connect circuits on the two chips. As shown in FIG. 1, a flip quantum chip includes an air bridge 101, an under bump metallization (UBM) layer 102, and a metal column solder joint 103.
Metal column solder joint: it is a solder joint structure formed by a superconductive element and is configured to implement a circuit connection between different chips. As shown in FIG. 1, the metal column solder joint 103 is formed on each of the top chip and the bottom chip.
UBM layer: it is disposed between a superconductive metal film layer on which a coplanar waveguide is located and a metal column solder joint, and is configured to prevent alloying of the metal column solder joint and the superconductive metal film layer on which the coplanar waveguide is located.
Coplanar waveguide: it is also referred to as a coplanar microstrip transmission line, and is composed of a central conductor (also referred to as a central strip) and semi-infinite ground planes (also referred to as ground strips) on two sides. As shown in FIG. 1, a coplanar waveguide composed of a central strip 104 and ground strips 105 is formed on the bottom chip.
Air bridge: it is a three-dimensional bridge structure made from a superconductive material, is usually disposed on a bottom chip, and is configured to connect infinite ground planes on two sides of a coplanar waveguide, or connect central conductors of two sections of discrete coplanar waveguides. As shown in FIG. 1, the air bridge 101 is configured to connect the ground strips 105 on two sides. The air bridge is classified into a discrete air bridge and a fully-inclusive air bridge. A difference between the discrete air bridge and the fully-inclusive air bridge lies in whether a bridge body of the air bridge is continuous.

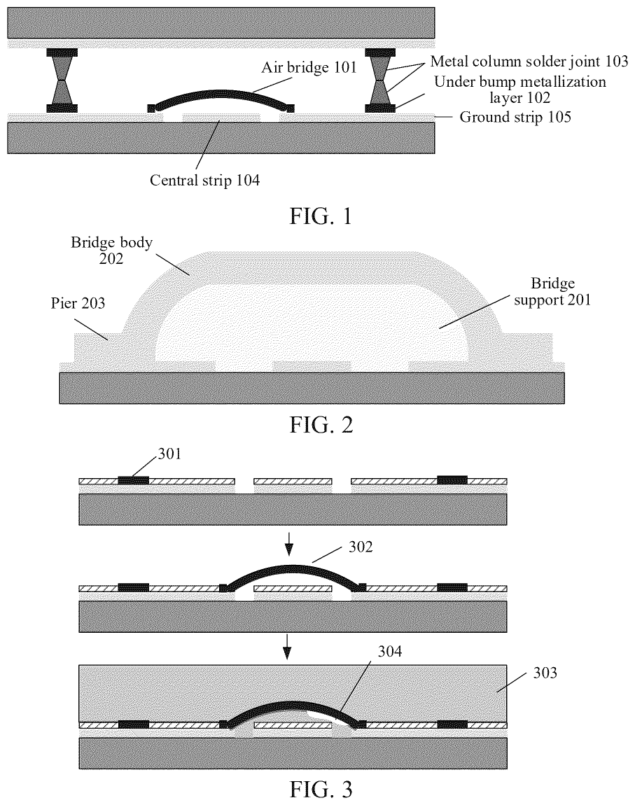

The air bridge is composed of a pier and a bridge body. Moreover, during preparation of the air bridge, a bridge support structure is first prepared, and then the air bridge, namely, the pier and the bridge body, is prepared based on the bridge support structure. After the air bridge is prepared, the bridge support is released, to complete preparation of the air bridge. FIG. 2 is a side view of an air bridge. A bridge support 201 is first prepared, a bridge body 202 and a pier 203 are then prepared based on the bridge support 201, to obtain an air bridge structure, and the bridge support 201 is released by a process, to obtain an air bridge.

A superconductive quantum chip transmits a microwave signal through a coplanar waveguide. As an operational capability of the quantum chip increases, there are more coplanar waveguides and more circuits on the quantum chip, which may cause the problem of signal crosstalk between the coplanar waveguides. In the related art, the problem of routing of the chip is relieved based on a flip chip packaging technology. As shown in FIG. 1, in the flip quantum chip, the two different chips are connected through the metal column solder joints 103. By distributing circuits on different chips, the problem of circuit congestion is relieved. Meanwhile, the air bridge is prepared on the coplanar waveguide to connect the ground planes on two sides of the coplanar waveguide, whereby the problem of signal crosstalk between different coplanar waveguides can be relieved.

During preparation of a superconductive flip quantum chip, because a metal column solder joint may form an alloy with a superconductive metal film layer corresponding to a coplanar waveguide on a substrate, a UBM layer is prepared between the metal column solder joint and the superconductive metal film layer to prevent the alloying. Moreover, a geometrical height of the air bridge is lower than that of the metal column solder joint in most cases, and correspondingly, a height of a photoresist for preparing the air bridge is less than that of a photoresist for preparing the metal column solder joint. Therefore, to prevent a pattern with a thickness greater than that of the photoresist from affecting formation of a uniform resist, the air bridge is usually first prepared, and then the metal column solder joint is prepared.

In the related art, a UBM layer, an air bridge, and a metal column solder joint are usually prepared in operations. As shown in FIG. 3, a UBM layer 301 is first prepared based on a photoresist on a substrate on which a coplanar waveguide is formed, an air bridge 302 is then prepared on the substrate, and finally, a metal column solder joint is prepared on the substrate including the UBM layer 301 and the air bridge 302. It can be seen that the operations of the process are complicated and require a plurality of times of exposure, and accordingly, the chip is easily damaged.

Furthermore, during preparation of the metal column solder joint, spin-coating of a photoresist is needed. Due to the liquidity of the photoresist, the photoresist flows to a space below a bridge body of the air bridge. For a fully-inclusive air bridge, because the liquidity of the photoresist below the bridge body is relatively poor, the space is not filled up with the photoresist, and an air cavity is formed. As shown in FIG. 3, a photoresist 303 is spin-coated on the substrate including the UBM layer 301 and the air bridge 302, and an air cavity 304 is formed below a bridge body of the air bridge 302. When the air cavity 304 exists, because the photoresist needs to be soft-baked at a high temperature, air remaining in the air cavity expands at a high temperature and contracts at a low temperature, and a bubble is formed on the air bridge 302. During subsequent vapor deposition of metal, the bubble may further expand, to compress the air bridge 302, whereby the yield of the air bridge is affected.

In addition, during preparation of the metal column solder joint, the photoresist may crack under pressure of an external environment. If the foregoing problem of bubbling occurs, stress exists in the photoresist, which is more likely to cause cracking of the photoresist. During subsequent vapor deposition of a solder joint material, the solder joint material fills up a crack and remains at a position corresponding to the substrate, whereby a circuit on the chip may be affected, and performance of the chip is affected.

To solve the foregoing problems, exemplary embodiments of this disclosure provide a preparation method for a quantum chip, which can simplify a preparation process of a flip quantum chip, and can avoid the problem of bubbling on an air bridge and the problem of remaining of a solder joint material, to improve performance of the chip. The method provided in the embodiments of this disclosure is exemplarily described below.

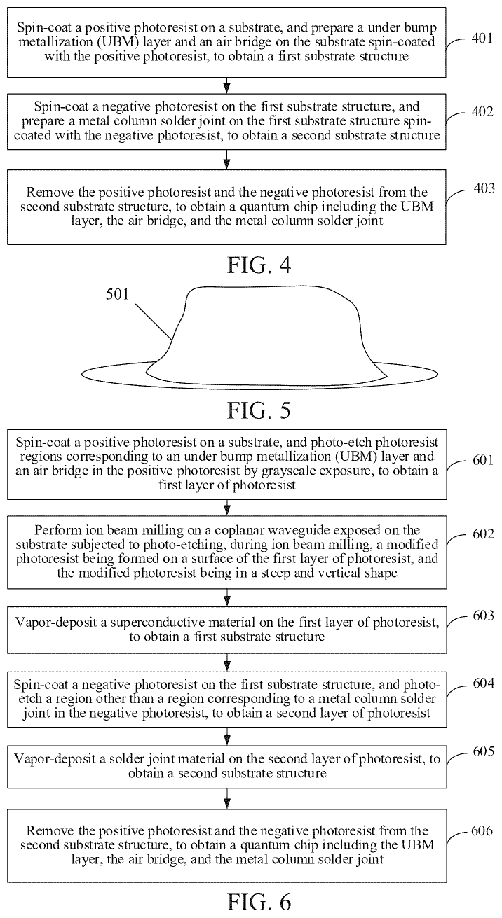

FIG. 4 is a flowchart of a preparation method for a quantum chip according to an exemplary embodiment of this disclosure. This exemplary embodiment is described by using an example in which the method is applied to a mask aligner. The method includes the following operations.

Operation 401: Spin-coat a positive photoresist on a substrate, and prepare a UBM layer and an air bridge on the substrate spin-coated with the positive photoresist, to obtain a first substrate structure.

The method provided in the exemplary embodiment of this disclosure is applied to preparation of a flip quantum chip of which a chip structure includes a UBM layer, an air bridge, and a metal column solder joint.

Preparation of the quantum chip requires a photoresist. According to whether an exposed region is removed or reserved during developing, a photoresist is classified into a positive photoresist and a negative photoresist. For the positive photoresist, an exposed region undergoes a chemical reaction and becomes soluble in a developer solution, an unexposed region is insoluble in the developer solution, and a formed photoresist pattern is the same as that of a mask. For the negative photoresist, an exposed region is insoluble in a developer solution due to cross-linking and curing, an unexposed region is soluble in the developer solution, and a formed photoresist pattern is contrary to that of a mask.

In an exemplary implementation, the mask aligner prepares, based on the positive photoresist, the UBM layer and the air bridge on the substrate having a coplanar waveguide. Moreover, during preparation of the UBM layer and the air bridge, the UBM layer and the air bridge may be prepared in an operation, or may be prepared in operations.

In some exemplary embodiments, the positive photoresist is an SPR220 photoresist or a 6350A photoresist.

In some exemplary embodiments, after the UBM layer and the air bridge are prepared, the first substrate structure including the UBM layer and the air bridge is obtained. Because the resist is not removed at this moment, the positive photoresist subjected to photo-etching remains on the first substrate structure.

Operation 402: Spin-coat a negative photoresist on the first substrate structure, and prepare a metal column solder joint on the first substrate structure spin-coated with the negative photoresist, to obtain a second substrate structure.

After preparing the UMB layer and the air bridge, the mask aligner prepares the metal column solder joint based on the first substrate structure from which the resist is not removed. After exposure and development of the negative photoresist, an inverted trapezoidal undercut structure is formed. The structure facilitates subsequent removal of the photoresist and formation of a metal column with a good profile. Therefore, the metal column solder joint may be prepared based on the negative photoresist. The metal column prepared based on the negative photoresist is not likely adhered to the photoresist and is easily removed. In addition, a regular trapezoidal metal column solder joint is formed, which can facilitate subsequent bonding. As shown in FIG. 5, a regular trapezoidal metal column solder joint 501 is prepared based on the negative photoresist.

In some exemplary embodiments, the negative photoresist is an E3510 photoresist.

In an exemplary implementation, the negative photoresist is spin-coated on the first substrate structure, and after exposure, development, and vapor deposition of a solder joint material, the metal column solder joint is prepared on the first substrate structure spin-coated with the negative photoresist.

During vapor deposition of the solder joint material, because the positive photoresist remains on the first substrate structure, that is, the positive photoresist remains below the bridge body of the air bridge, whereby the problem of formation of an air cavity below the bridge body due to the liquidity of the negative photoresist is avoided, and accordingly, the problem of bubbling can be avoided.

Furthermore, in a case that the negative photoresist for spin-coating cracks, the positive photoresist can protect the substrate, and can prevent the solder joint material from filling a crack to remain on the substrate, and accordingly, improves quality of the chip.

Operation 403: Remove the positive photoresist and the negative photoresist from the second substrate structure, to obtain a quantum chip including the UBM layer, the air bridge, and the metal column solder joint.

After the UBM layer, air bridge, and metal column solder joint structures are all prepared, the residual positive photoresist and the residual negative photoresist may be removed at one time, to complete the preparation of the quantum chip. After the preparation is completed, a flip quantum chip may be obtained by bonding.

In some exemplary embodiments, the mask aligner removes the photoresists by at least one of a dry method and a wet method. The dry method is to remove a photoresist by ashing. For example, the photoresists are removed by the dry method alone, the photoresists are removed by the wet method alone, or the photoresists are removed by the dry method first and then by the wet method.

In an exemplary implementation, the mask aligner peels off the photoresists by immersing the photoresists in a resist removing solution. During peeling, the positive photoresist and the negative photoresist are dissolved in the resist removing solution, and the quantum chip including only the UBM layer, the air bridge, and the metal column solder joint is obtained.

In conclusion, in the exemplary embodiments of this disclosure, after the UBM layer and the air bridge are prepared based on the positive photoresist, and the metal column solder joint is prepared based on the negative photoresist, the resists are removed together, and the flip quantum chip including the UBM layer, air bridge, and metal column solder joint structures is obtained. That is, by combining the positive photoresist with the negative photoresist, one-time resist removal and molding can be realized, whereby preparation efficiency can be improved. Moreover, because the positive photoresist is not removed during preparation of the metal column solder joint, that is, the positive photoresist remains below a bridge body of the air bridge, an air cavity is not formed, whereby the problem of bubbling can be avoided, and performance of the air bridge can be improved. Furthermore, if the negative photoresist cracks during preparation of the metal column solder joint based on the negative photoresist, the residual positive photoresist further protects the substrate, to prevent a metallic filament from remaining on the substrate due to cracks, and accordingly, improves the yield of a quantum chip and performance of the chip.

During preparation of the UBM layer and the air bridge, the UBM layer and the air bridge may be simultaneously prepared based on the positive photoresist. That is, the UBM layer and the air bridge are prepared by one-time exposure, whereby the process is simplified. Descriptions are provided below by using an exemplary embodiment.

FIG. 6 is a flowchart of a preparation method for a quantum chip according to another exemplary embodiment of this disclosure. The method includes the following operations.

Operation 601: Spin-coat a positive photoresist on a substrate, and photo-etch photoresist regions corresponding to a UBM layer and an air bridge in the positive photoresist by grayscale exposure, to obtain a first layer of photoresist.

In an exemplary implementation, the mask aligner first spin-coats the positive photoresist on the substrate having a coplanar waveguide. In some exemplary embodiments, a thickness of the positive photoresist is determined according to a height of the air bridge. The thickness of the positive photoresist is greater than that of the air bridge.

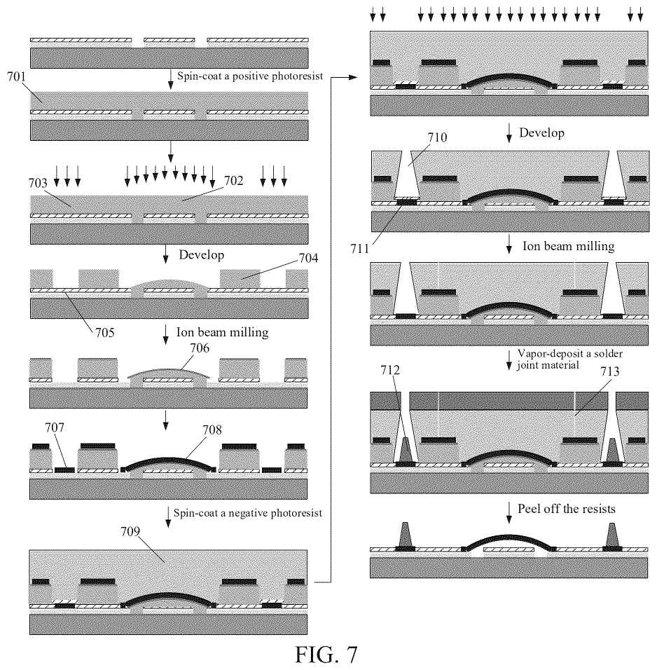

Exemplarily, a layer of positive photoresist with a thickness greater than 3 um is spin-coated. As shown in FIG. 7, a positive photoresist 701 is spin-coated on a substrate.

Then, the mask aligner exposes the photoresist regions corresponding to the UBM layer and the air bridge in the positive photoresist by grayscale exposure. Grayscale exposure refers to use of different exposure light intensities for different positions in a photoresist. An exposure depth of the positive photoresist is controlled by controlling an exposure light intensity, to obtain a required pattern. In an exemplary implementation, the operation of photo-etching, by the mask aligner, photoresist regions corresponding to a UBM layer and an air bridge in the positive photoresist by grayscale exposure includes operation 601a to operation 601c (not shown in the figure).

Operation 601a: Determine, based on a bridge support structure of the air bridge, an exposure light intensity for the photoresist region corresponding to the air bridge, the exposure light intensity being in a positive correlation with a distance between a bridge body in the bridge support structure and a surface of the positive photoresist.

In an exemplary implementation, a relationship between a light intensity at a depth x away from the surface of the photoresist (that is, at a position x away from the surface of the photoresist) and an initial light intensity is expressed by the following formula:

$$I ( x ) = {I}_{0} exp ( - x / ζ )$$

where, I₀ indicates the initial light intensity (which refers to an exposure light intensity), and ξ is a constant.

In an exemplary implementation, the mask aligner determines, according to a required bridge support structure of the air bridge, a distance between each position on the bridge body of the air bridge and the surface of the positive photoresist, and determines, according to the light intensity for exposing the photoresist to the depth x, the initial light intensity I₀ corresponding to each position. In this way, a bridge support obtained after photo-etching is of an arch-shaped structure with a required size.

Operation 601b: Perform grayscale exposure on the photoresist regions corresponding to the air bridge and the UBM layer in the positive photoresist based on exposure light intensities corresponding to different positions.

After the exposure light intensities corresponding to the positions are determined, the mask aligner performs grayscale exposure on the photoresist region corresponding to the air bridge according to the exposure light intensities corresponding to the different positions. In this way, the photoresist region above the bridge body of the air bridge is fully exposed, and is dissolved after being developed, to form an arch-shaped bridge support.

The mask aligner may expose the photoresist region corresponding to the UBM layer based on a same exposure light intensity, to fully expose the entire photoresist region above the UBM layer. As shown in FIG. 7, grayscale exposure is performed on a photoresist region 702 corresponding to the air bridge and a photoresist region 703 corresponding to the UBM layer (in the figure, a length of an arrow indicates a size of an exposure light intensity).

By grayscale exposure, the photoresist region corresponding to the air bridge and the photoresist region corresponding to the UBM layer need to be exposed at one time, which shortens the process, and reduces a damage probability of the chip.

In an exemplary implementation, during exposure, the mask aligner covers a mask on a region other than to-be-exposed regions in the positive photoresist, and then emits light to perform exposure.

Operation 601c: Develop the positive photoresist subjected to exposure, to obtain a first layer of photoresist.

Development is further performed after exposure, and the exposed photoresist regions are dissolved, to complete photo-etching of the photoresist regions corresponding to the air bridge and the UBM layer. The region in the positive photoresist that is not photo-etched is taken as the first layer of photoresist.

Exemplarily, as shown in FIG. 7, after development, a first layer of photoresist 704 that is not photo-etched is obtained.

Operation 602: Perform ion beam milling on a coplanar waveguide exposed on the substrate subjected to photo-etching, during ion beam milling, a modified photoresist being formed on a surface of the first layer of photoresist, and the modified photoresist exhibiting a steep and vertical profile.

Because a native oxide layer exists in a superconductive metal film layer on which the coplanar waveguide is located, to ensure a good superconductive contact, the mask aligner needs to perform ion beam milling on the coplanar waveguide exposed on the substrate subjected to photo-etching, to remove the native oxide layer, which prevents the native oxide layer from affecting the superconductive contact.

In an exemplary implementation, the mask aligner bombards, in a 1E-4 Torr vacuum environment, the superconductive metal film layer on which the coplanar waveguide is located with Ar ions at 7 sccm for 5 min.

During ion beam milling, the entire substrate undergoes ion bombardment, that is, the first layer of photoresist on the substrate also undergoes ion bombardment at the same time, and a layer of modified photoresist is formed on the surface of the photoresist. By grayscale exposure, the photoresist exhibits a steep and vertical profile, that is, a steep and vertical side wall is formed by the photoresist at an edge of the air bridge. Therefore, during subsequent resist removal, the modified photoresist is removed along with an unmodified photoresist below, which does not affect resist removal and quality of the chip.

Exemplarily, as shown in FIG. 7, the mask aligner performs ion beam milling on the coplanar waveguide exposed on the substrate subjected to photo-etching, to remove a native oxide layer 705 and form a modified photoresist 706 on the surface of the first layer of photoresist.

Operation 603: Vapor-deposit a superconductive material on the first layer of photoresist, to obtain a first substrate structure.

After ion beam milling, the superconductive material is vapor-deposited. In an exemplary implementation, the mask aligner vapor-deposits the superconductive material in situ. In situ refers to that a multi-operation process is performed in a single vacuum cavity or in a plurality of connected vacuum cavities. In this exemplary embodiment, the mask aligner performs ion beam milling and vapor deposition of the superconductive material in a vacuum cavity, to prevent formation of a native oxide layer on the surface of the superconductive metal film layer due to exposure to the air before the superconductive material is vapor-deposited.

During vapor deposition of the superconductive material, the mask aligner vapor-deposits a layer of superconductive material on each of the region corresponding to the UBM layer and the region corresponding to the air bridge, to form a UBM layer structure and an air bridge structure. That is, the vapor-deposited superconductive material not only forms the air bridge, but also forms the UBM layer. In some exemplary embodiments, the superconductive material is titanium nitride (TiN), niobium (Nb), or the like, which is not specifically defined in the exemplary embodiments of this disclosure.

The UBM layer is configured to prevent alloying of the metal column solder joint and the superconductive metal film layer on which the coplanar waveguide is located. Therefore, the superconductive material for preparing the UBM layer needs not to form an alloy with the superconductive metal film layer corresponding to the coplanar waveguide, nor to form an alloy with the solder joint material corresponding to the metal column solder joint. In other words, selection of the superconductive material is based on the materials of the superconductive metal film layer and the metal column solder joint.

Exemplarily, when the superconductive metal film layer on which the coplanar waveguide is located is made from aluminum (AI), and the solder joint material of the metal column solder joint is indium (In), the superconductive material is Nb. The mask aligner vapor-deposits a layer of superconductive material Nb with a thickness greater than 300 nm is situ on the first layer of photoresist.

In an exemplary implementation, the UBM layer structure and the air bridge structure are formed after the superconductive material is vapor-deposited on the first layer of photoresist, and the first substrate structure including the UBM layer and the air bridge is obtained. As shown in FIG. 7, a UBM layer 707 and an air bridge 708 are formed after the superconductive material is vapor-deposited, and a first substrate structure including the UBM layer, the air bridge, and the residual positive photoresist is obtained.

Operation 604: Spin-coat a negative photoresist on the first substrate structure, and photo-etch a region other than a region corresponding to the metal column solder joint in the negative photoresist, to obtain a second layer of photoresist.

In an exemplary embodiment of this disclosure, after the UBM layer and the air bridge are prepared based on the positive photoresist, the mask aligner directly prepares the metal column solder joint based on the substrate from which the resist is not removed, and removes the resists at one time after completing preparation of the metal column solder joint.

In an exemplary implementation, the mask aligner prepares the metal column solder joint based on the negative photoresist. The mask aligner first spin-coats a layer of negative photoresist on the first substrate structure. A thickness of the negative photoresist is determined according to a height of a to-be-prepared metal column solder joint. The thickness of the negative photoresist is greater than the height of the metal column solder joint. In some exemplary embodiments, the height of the metal column solder joint is 10 um, and the thickness of the negative photoresist is greater than 10 um. Exemplarily, an E3510 negative photoresist with a thickness of 16 um is spin-coated on the first substrate structure. As shown in FIG. 7, a negative photoresist 709 is spinner-coated on the first substrate structure.

After the negative photoresist is spin-coated, photo-etching is performed. Because the negative photoresist is adopted, the region other than the region corresponding to the metal column solder joint in the negative photoresist is photo-etched. In this way, the photoresist in the region other than the region corresponding to the metal column solder joint is reserved, and the photoresist in the region corresponding to the metal column solder joint is removed.

A photo-etching process may include operation 604a and operation 604b (not shown in the figure).

Operation 604a: Expose a photoresist region other than a photoresist region corresponding to the metal column solder joint in the negative photoresist.

Contrary to photo-etching of the positive photoresist, the mask aligner exposes the photoresist region other than the photoresist region corresponding to the metal column solder joint. In some exemplary embodiments, the mask aligner performs exposure by using ultraviolet light.

Operation 604b: Develop the negative photoresist subjected to exposure, to obtain a second layer of photoresist.

The mask aligner performs development after exposure. In this way, the negative photoresist that is in the region corresponding to the metal column solder joint and that is unexposed is dissolved, to form an undercut structure, and the residual undissolved negative photoresist forms the second layer of photoresist.

Exemplarily, as shown in FIG. 7, the mask aligner exposes a region other than a region corresponding to the metal column solder joint in the negative photoresist 709, and then performs development by using a developer solution, to form an undercut structure 710.

Operation 605: Vapor-deposit a solder joint material on the second layer of photoresist, to obtain a second substrate structure.

After the photo-etching is completed, the solder joint material is vapor-deposited, to prepare the metal column solder joint. The substrate is not in a vacuum environment during spin-coating of the negative photoresist, and consequently, a native oxide layer is formed on the surface of the UMB layer. As shown in FIG. 7, a native oxide layer 711 is formed on the UBM layer (a superconductive material at another position is also oxidized, and only the native oxide layer on the UBM layer is shown in the figure). Therefore, to ensure a good superconductive contact, before vapor-depositing the solder joint material, the mask aligner needs to perform ion beam milling, to remove the native oxide layer on the UBM layer.

In an exemplary implementation, after ion beam milling, to prevent a native oxide layer from being formed again, the mask aligner vapor-deposits the solder joint material in situ. Because the photoresist in the region corresponding to the metal column solder joint is removed, the mask aligner deposits a layer of solder joint material on the UBM layer, to form the metal column solder joint.

In some exemplary embodiments, the solder joint material is In, and an In column solder joint is prepared on the UBM layer. Exemplarily, In with a thickness of 10 um is vapor-deposited, to form the In column solder joint. As shown in FIG. 7, the mask aligner first performs ion beam milling, to remove the native oxide layer 711 on the UBM layer, and then vapor-deposits a layer of solder joint material in situ, to form a metal column solder joint 712.

During ion beam milling, due to ion bombardment, the negative photoresist may crack. During vapor deposition, a crack may be filled with the solder joint material. However, because the first layer of photoresist (the positive photoresist) located below is not likely to crack (because the thickness is less than that of the negative photoresist), the first layer of lower photoresist can block the solder joint material, to avoid the problem of remaining of the solder joint material. As shown in FIG. 7, the negative photoresist 709 cracks to form a crack 713, and the positive photoresist located below provides a protective function, whereby the solder joint material does not remain on the coplanar waveguide of the substrate.

The second substrate structure including the metal column solder joint is obtained after vapor deposition of the solder joint material.

Operation 606: Remove the positive photoresist and the negative photoresist from the second substrate structure, to obtain a quantum chip including the UBM layer, the air bridge, and the metal column solder joint.

After preparing the metal column solder joint, the mask aligner performs resist removal, and remove both the positive photoresist and the negative photoresist, to complete preparation of the chip.

Exemplarily, as shown in FIG. 7, a quantum chip including the UBM layer, the air bridge, and the metal column solder joint is obtained after the resists are peeled off.

In this exemplary embodiment, the UBM layer and the air bridge are prepared by one-time exposure, whereby the process can be simplified, and a damage probability of the chip during exposure can be reduced. Moreover, compared with a positive photoresist, a metal column solder joint prepared based on a negative photoresist is not likely adhered to the negative photoresist, and the metal column solder joint exhibits a relatively good profile.

In the foregoing exemplary embodiments, the bridge body of the air bridge is prepared by grayscale exposure, and an arch-shaped bridge support structure is formed. In another possible implementation, the bridge body of the air bridge is prepared by reflow. Descriptions are provided below by using an exemplary embodiment.

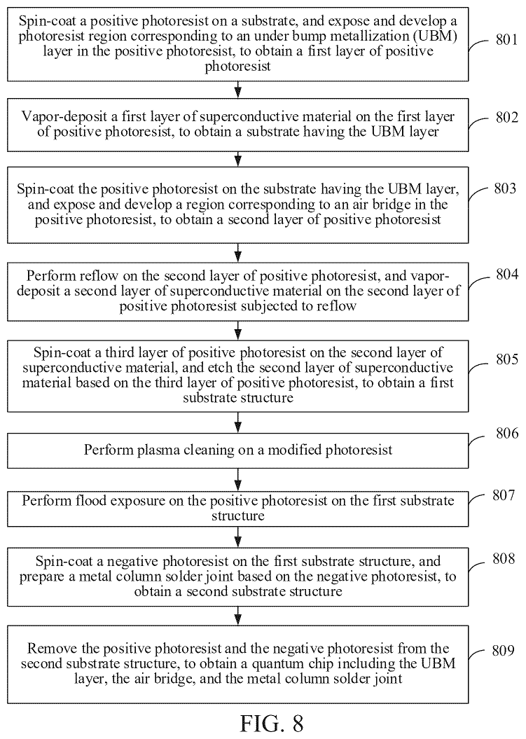

FIG. 8 is a flowchart of a preparation method for a quantum chip according to another exemplary embodiment of this disclosure. The method includes the following operations.

Operation 801: Spin-coat a positive photoresist on a substrate, and expose and develop a photoresist region corresponding to a UBM layer in the positive photoresist, to obtain a first layer of positive photoresist.

In an exemplary implementation, the UBM layer and an air bridge are prepared in operations. During preparation of the UBM layer, a mask aligner first spin-coats the positive photoresist on the substrate, and then photo-etches the photoresist region corresponding to the UBM layer, that is, performs exposure and development, to obtain the first layer of positive photoresist. The first layer of positive photoresist is the residual positive photoresist obtained after the photoresist in the region corresponding to the UBM layer is removed.

Operation 802: Vapor-deposit a first layer of superconductive material on the first layer of positive photoresist, and peel off the first layer of positive photoresist to obtain a substrate having the UBM layer.

The mask aligner vapor-deposits the first layer of superconductive material on the first layer of positive photoresist, to form the UBM layer. Moreover, before vapor deposition, ion beam milling may be first performed, to remove a native oxide layer formed on a UBM region corresponding to a coplanar waveguide. In this way, the UBM layer obtained by vapor deposition can be in a good superconductive contact with a superconductive metal film layer on which the coplanar waveguide is located.

In some exemplary embodiments, the first layer of superconductive material is TiN, Nb or the like.

Moreover, after completing preparation of the UBM layer, the mask aligner peels off the first layer of positive photoresist, to obtain the substrate having the UBM layer.

Operation 803: Spin-coat a positive photoresist on the substrate having the UBM layer, and expose and develop a region corresponding to an air bridge in the positive photoresist, to obtain a second layer of positive photoresist.

After the substrate having the UBM layer is prepared, the air bridge is prepared. In an exemplary implementation, during preparation of the air bridge, the mask aligner spin-coats the positive photoresist on the substrate, and then exposes and develops a photoresist region corresponding to a pier of the air bridge, to obtain the second layer of positive photoresist.

Operation 804: Perform reflow on the second layer of positive photoresist, and vapor-deposit a second layer of superconductive material on the second layer of positive photoresist subjected to reflow.

After photo-etching the pier, the mask aligner performs reflow on the second layer of positive photoresist. Reflow refers to a process in which a photoresist is baked to a specific temperature, to cause a change in a profile of a photoresist side wall. In an exemplary implementation, the mask aligner changes a photoresist side wall corresponding to the pier into a circular arc by high-temperature reflow, to obtain an arch-shaped photoresist for preparing a bridge support structure. In some exemplary embodiments, the mask aligner heats the substrate at a high temperature, to reflow the positive photoresist.

After reflow, the second layer of superconductive material is vapor-deposited, to prepare the air bridge. This process may include operation 804a and operation 804b (not shown in the figure).

Operation 804a: Perform ion beam milling on a coplanar waveguide exposed on the substrate subjected to reflow, during ion beam milling, a modified photoresist being formed on a surface of the second layer of positive photoresist, and the modified photoresist being in a continuous shape.

A native oxide layer exists on the coplanar waveguide (that is, a coplanar waveguide corresponding to the pier) exposed on the substrate. To ensure a good superconductive contact between the air bridge and the coplanar waveguide, ion beam milling needs to be first performed.

During ion beam milling, the modified photoresist is formed on the surface of the second layer of positive photoresist. Moreover, due to reflow, the modified photoresist is in a continuous shape. That is, a continuous modified photoresist (it is adhered to a pier of the air bridge) is formed on an edge of the air bridge. Therefore, resist removal needs to be performed subsequently.

Operation 804b: Vapor-deposit a second layer of superconductive material on the second layer of positive photoresist subjected to ion beam milling.

After ion beam milling, the mask aligner deposits the second layer of superconductive material on the second layer of positive photoresist, to prepare the air bridge.

Operation 805: Spin-coat a third layer of positive photoresist on the second layer of superconductive material, and etch the second layer of superconductive material based on the third layer of positive photoresist, to obtain the first substrate structure.

However, because the vapor-deposited superconductive material covers an upper layer of an entire sample, the superconductive material further needs to be etched, to obtain the bridge body and the pier of the air bridge. In an exemplary implementation, a superconductive material region other than a superconductive material region corresponding to the air bridge is removed by using an etching solution.

To prevent the bridge body and the pier of the air bridge from being etched by the etching solution, a photoresist may be coated on the bridge body and the pier, to achieve a protective effect. In this process, the mask aligner first spin-coats the third layer of positive photoresist on the second layer of superconductive material, and exposes and develops a photoresist region other than a photoresist region corresponding to the bridge body and the pier of the air bridge, to reserve only the positive photoresist on the bridge body and the pier of the air bridge. Then, etching is performed, that is, the superconductive material region other than the superconductive material region corresponding to the bridge body and the pier is etched, to prepare the air bridge, and the first substrate structure is obtained. That is, the first substrate structure includes the UBM layer, the air bridge, and the residual positive photoresist.

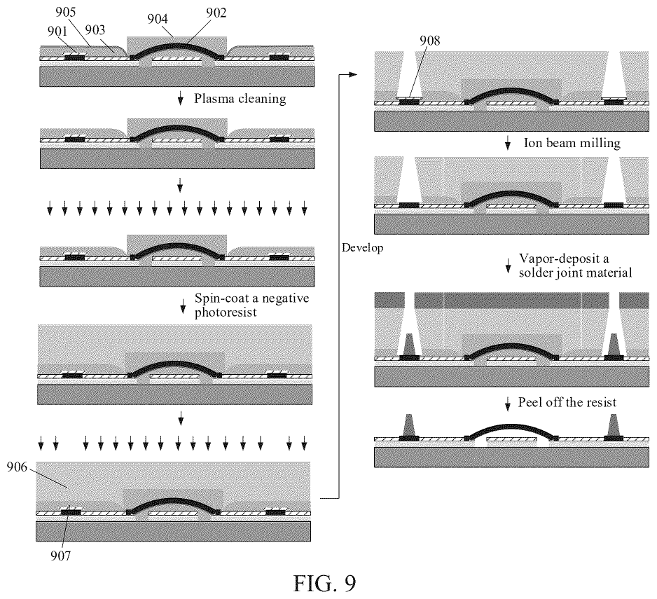

Exemplarily, as shown in FIG. 9, a first substrate structure includes a UBM layer 901, an air bridge 902, a second layer of positive photoresist 903, and a third layer of positive photoresist 904.

Operation 806: Perform plasma cleaning on the modified photoresist.

In the foregoing process, ion beam milling is performed to generate the modified photoresist. Because the bridge support structure is prepared by reflow, the modified photoresist is in a continuous shape and cannot be removed along with an unmodified positive photoresist located below. Therefore, the mask aligner needs to first remove the modified photoresist by plasma cleaning.

Exemplarily, as shown in FIG. 9, the mask aligner removes a modified photoresist 905 on the second layer of positive photoresist 903 by plasma cleaning.

In an exemplary implementation, the modified photoresist on the surface is removed by oxygen plasma cleaning. For example, the photoresist is cleaned O₂ plasma at 5 sccm, 100 Pa, and 300 W for 2 min, to remove the modified photoresist adhered to the pier of the air bridge.

Operation 807: Perform flood exposure on the positive photoresist on the first substrate structure.

In this exemplary embodiment, the metal column solder joint is prepared based on the substrate from which the positive photoresist is not removed. However, in the foregoing process of preparing the UBM layer and the air bridge in operations, the second layer of positive photoresist remains on the UBM layer during preparation of the air bridge. Therefore, the second layer of positive photoresist located above needs to be removed, to expose the UBM layer, and a metal column solder joint is prepared on the UBM layer. Therefore, the mask aligner first performs flood exposure on the positive photoresist on the first substrate structure. Flood exposure refers to maskless exposure of a positive photoresist. Then, during sequent development, the positive photoresist on the UBM layer is dissolved.

Exemplarily, the mask aligner performs flood exposure with ultraviolet light at 9 mW/cm² for 10 s.

Operation 808: Spin-coat a negative photoresist on the first substrate structure, and prepare a metal column solder joint on the first substrate structure spin-coated with the negative photoresist, to obtain a second substrate structure.

After flood exposure, the negative photoresist is spin-coated on the first substrate structure, and the metal column solder joint is prepared based on the negative photoresist. During preparation, the mask aligner first exposes the negative photoresist in a region other than a region corresponding to the metal column solder joint, then performs development. During development, the unexposed negative photoresist is dissolved, that is, the negative photoresist in the region corresponding to the metal column solder joint is dissolved. Meanwhile, because flood exposure is performed on the positive photoresist in advance, the positive photoresist on the UBM layer is also dissolved.

Exemplarily, as shown in FIG. 9, a negative photoresist 906 is spin-coated on the first substrate structure, a negative photoresist region other than a negative region corresponding to the metal column solder joint is exposed, and then development is performed. During development, both the positive photoresist 907 and the negative photoresist 906 on the UBM layer are dissolved.

After the photoresist is photo-etched, ion beam milling may be first performed to remove a native oxide layer, a solder joint material is vapor-deposited in situ, to form the metal column solder joint, and the second substrate structure is obtained.

As shown in FIG. 9, after ion beam milling, a native oxide layer 908 on the UBM layer is removed, and then a solder joint material is vapor-deposited in situ, to prepare a metal column solder joint.

Operation 809: Remove the positive photoresist and the negative photoresist from the second substrate structure, to obtain a quantum chip including the UBM layer, the air bridge, and the metal column solder joint.

For an implementation of this operation, refer to the foregoing operation 606. Details are not described in this exemplary embodiment again.

In this exemplary embodiment, the air bridge is prepared by reflow. In this process, the generated modified photoresist is removed by plasma cleaning, and by additional flood exposure, the metal column solder joint is prepared based on the negative photoresist without removing the positive photoresist. That is, the UBM layer, the air bridge, and the metal column solder joint are prepared by one-time resist removal, whereby the process can be simplified. Moreover, the positive photoresist can protect the air bridge structure and the substrate, and accordingly, improves quality of the air bridge and performance of the chip.

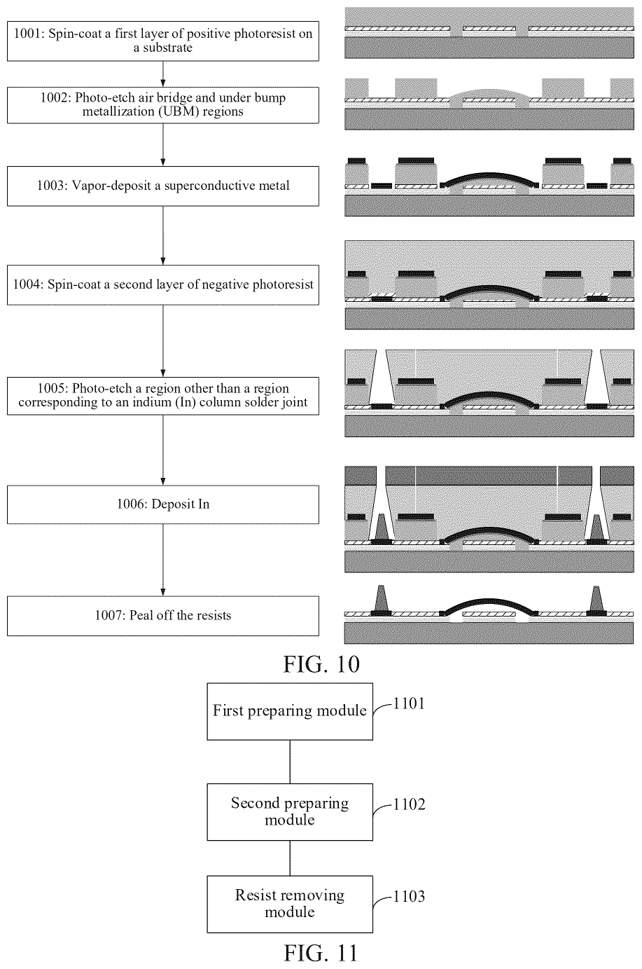

In an exemplary implementation, the metal column solder joint is an In column solder joint. FIG. 10 is a flowchart of a complete preparation process of a quantum chip according to an exemplary embodiment of this disclosure. Descriptions are provided below by taking grayscale exposure as an example. The process includes:

Operation 1001: Spin-coat a first layer of positive photoresist on a substrate.

In some exemplary embodiments, a mask aligner spin-coats a first layer of positive photoresist with a thickness greater than 3 um on a substrate having a coplanar waveguide. The positive photoresist is SPR220, 6350A or the like.

Operation 1002: Photo-etch air bridge and UBM regions.

In some exemplary embodiments, the mask aligner exposes the air bridge and UBM regions by grayscale exposure, and then perform development after exposure, to complete photo-etching.

Operation 1003: Vapor-deposit a superconductive metal.

In some exemplary embodiments, the superconductive metal is Nb. The mask aligner first bombards, in a 1E-4 Torr vacuum environment, a superconductive metal film layer on which the coplanar waveguide is located Ar ions at 7 sccm for 5 min, and then vapor-deposits a layer of superconductive metal with a thickness greater than 300 nm in situ. As shown in FIG. 10, a substrate including a positive photoresist, an air bridge, and a UBM layer is obtained after vapor deposition of a superconductive metal.

Operation 1004: Spin-coat a second layer of negative photoresist.

In some exemplary embodiments, the mask aligner spin-coats an E3510 negative photoresist with a thickness of 16 um.

Operation 1005: Photo-etch a photoresist region other than a photoresist region corresponding to an In column solder joint.

The mask aligner may expose and develop the photoresist region other than the photoresist region corresponding to the In column solder joint, to remove the negative photoresist in the region corresponding to the In column solder joint.

Operation 1006: Deposit In.

Before vapor-depositing In, the mask aligner first needs to perform ion beam milling to remove a native oxide layer on the UBM. After ion beam milling, vapor-deposition is performed, to obtain an In column solder joint.

Operation 1007: Peel off the resists.

In some exemplary embodiments, the mask aligner peels off the resists by using a resist removing solution, to remove the first layer of positive photoresist and the second layer of negative photoresist.

FIG. 11 is a structural block diagram of a preparation apparatus for a quantum chip according to an exemplary embodiment of this disclosure. The apparatus includes:
a first preparing module 1101, configured to spin-coat a positive photoresist on a substrate, and prepare a UBM layer and an air bridge on the substrate spin-coated with the positive photoresist, to obtain a first substrate structure;
a second preparing module 1102, configured to spin-coat a negative photoresist on the first substrate structure, and prepare a metal column solder joint on the first substrate structure spin-coated with the negative photoresist, to obtain a second substrate structure; and
a resist removing module 1103, configured to remove the positive photoresist and the negative photoresist from the second substrate structure, to obtain a quantum chip including the UBM layer, the air bridge, and the metal column solder joint.

In some exemplary embodiments, the first preparing module 1101 is configured to:
photo-etch photoresist regions corresponding to the UBM layer and the air bridge in the positive photoresist by grayscale exposure, to obtain a first layer of photoresist; and
vapor-deposit a superconductive material on the first layer of photoresist, to obtain the first substrate structure.

In some exemplary embodiments, the first preparing module 1101 is configured to:
determine an exposure light intensity for the photoresist region corresponding to the air bridge based on a bridge support structure of the air bridge, the exposure light intensity being in a positive correlation with a distance between a bridge body in the bridge support structure and a surface of the positive photoresist;
perform grayscale exposure on the photoresist regions corresponding to the air bridge and the UBM layer in the positive photoresist based on exposure light intensities corresponding to different positions; and
develop the positive photoresist subjected to exposure, to obtain the first layer of photoresist.

In some exemplary embodiments, an ion beam milling module, configured to:
perform ion beam milling on a coplanar waveguide exposed on the substrate subjected to photo-etching, during ion beam milling, a modified photoresist being formed on a surface of the first layer of photoresist, and the modified photoresist being in a steep and vertical shape.

In some exemplary embodiments, the first preparing module 1101 is configured to:
expose and develop a photoresist region corresponding to the UBM layer in the positive photoresist, to obtain a first layer of positive photoresist;
vapor-deposit a first layer of superconductive material on the first layer of positive photoresist, and peel off the first layer of positive photoresist to obtain a substrate having the UBM layer;
spin-coat the positive photoresist on the substrate having the UBM layer, and expose and develop a region corresponding to the air bridge in the positive photoresist, to obtain a second layer of positive photoresist;
perform reflow on the second layer of positive photoresist, and vapor-deposit a second layer of superconductive material on the second layer of positive photoresist subjected to reflow; and
spin-coat a third layer of positive photoresist on the second layer of superconductive material, and etch the second layer of superconductive material based on the third layer of positive photoresist, to obtain the first substrate structure.

In some exemplary embodiments, the first preparing module 1101 is configured to:
perform ion beam milling on a coplanar waveguide exposed on the substrate subjected to reflow, during ion beam milling, a modified photoresist being formed on a surface of the second layer of positive photoresist, and the modified photoresist being in a continuous shape; and
vapor-deposit the second layer of superconductive material on the second layer of positive photoresist subjected to ion beam milling.

The resist removing module is further configured to perform plasma cleaning on the modified photoresist.

In some exemplary embodiments, the apparatus further includes:
a flood exposure module, configured to perform flood exposure on the positive photoresist on the first substrate structure.

In some exemplary embodiments, the second preparing module 1102 is configured to:
photo-etch a region other than a region corresponding to the metal column solder joint in the negative photoresist, to obtain a second layer of photoresist; and
vapor-deposit a solder joint material on the second layer of photoresist, to obtain the second substrate structure.

In some exemplary embodiments, the second preparing module 1102 is configured to:
expose the photoresist region other than the region corresponding to the metal column solder joint in the negative photoresist; and
develop the negative photoresist subjected to exposure, to obtain the second layer of photoresist.

In some exemplary embodiments, a superconductive material for preparing the UBM layer does not form an alloy with the superconductive metal film layer corresponding to the coplanar waveguide, and does not form an alloy with the solder joint material corresponding to the metal column solder joint.

In some exemplary embodiments, the superconductive material for preparing the UBM layer and the air bridge is Nb, and the solder joint material for preparing the metal column solder joint is In.

Exemplary embodiments of this disclosure further provide a mask aligner. The mask aligner includes a photo-etching component, a processor, and a memory. The memory has at least one instruction stored therein, and the at least one instruction, when loaded by the processor, controls the photo-etching component to implement the preparation method for a quantum chip described in the foregoing exemplary embodiments.

Exemplary embodiments of this disclosure further provide a quantum chip of which a chip structure includes a UBM layer, an air bridge, and a metal column solder joint. The quantum chip is prepared by the preparation method for a quantum chip described in the foregoing exemplary embodiments.

Exemplary embodiments of this disclosure further provide a quantum computer. The quantum computer includes the quantum chip described in the foregoing exemplary embodiments.

The foregoing descriptions are merely alternative exemplary embodiments of this application, but are not intended to limit this application. Any modification, equivalent replacement, or improvement made within the spirit and principle of this application fall within the scope of protection of this application. Additionally, the word “preparing” that has been used in the foregoing descriptions is also understood to be “forming”, “making”, or “manufacturing” in some embodiments.

What is claimed is:

1. A method for preparing a quantum chip by a mask aligner, comprising:
spin-coating a positive photoresist on a substrate, and preparing an under bump metallization (UBM) layer and an air bridge on the substrate spin-coated with the positive photoresist, to obtain a first substrate structure;
spin-coating a negative photoresist on the first substrate structure, and preparing a metal column solder joint on the first substrate structure spin-coated with the negative photoresist, to obtain a second substrate structure; and
removing the positive photoresist and the negative photoresist from the second substrate structure, to obtain a quantum chip comprising the UBM layer, the air bridge, and the metal column solder joint.

2. The method according to claim 1, wherein preparing the UBM layer and the air bridge on the substrate spin-coated with the positive photoresist comprises:
photo-etching photoresist regions corresponding to the UBM layer and the air bridge in the positive photoresist by grayscale exposure, to obtain a first layer of photoresist; and
vapor-depositing a superconductive material on the first layer of photoresist, to obtain the first substrate structure.

3. The method according to claim 2, wherein the photo-etching photoresist regions corresponding to the UBM layer and the air bridge in the positive photoresist by grayscale exposure comprises:
determining an exposure light intensity for the photoresist region corresponding to the air bridge based on a bridge support structure of the air bridge, the exposure light intensity being in a positive correlation with a distance between a bridge body in the bridge support structure and a surface of the positive photoresist;
performing grayscale exposure on the photoresist regions corresponding to the air bridge and the UBM layer in the positive photoresist based on exposure light intensities corresponding to different positions; and
developing the positive photoresist subjected to exposure, to obtain the first layer of photoresist.

4. The method according to claim 2, wherein after photo-etching the photoresist regions corresponding to the UBM layer and the air bridge in the positive photoresist by grayscale exposure, the method further comprises:
performing ion beam milling on a coplanar waveguide exposed on the substrate subjected to photo-etching, and forming a modified photoresist on a surface of the first layer of photoresist during ion beam milling, the modified photoresist being in a steep and vertical shape.

5. The method according to claim 1, wherein preparing the UBM layer and the air bridge on the substrate spin-coated with the positive photoresist comprises:
exposing and developing a photoresist region corresponding to the UBM layer in the positive photoresist, to obtain a first layer of positive photoresist;
vapor-depositing a first layer of superconductive material on the first layer of positive photoresist, and removing the first layer of positive photoresist to obtain a substrate having the UBM layer;
spin-coating the positive photoresist on the substrate having the UBM layer, and exposing and developing a region corresponding to the air bridge in the positive photoresist, to obtain a second layer of positive photoresist;
performing reflow on the second layer of positive photoresist, and vapor-depositing a second layer of superconductive material on the second layer of positive photoresist subjected to reflow; and
spin-coating a third layer of positive photoresist on the second layer of superconductive material, and etching the second layer of superconductive material based on the third layer of positive photoresist, to obtain the first substrate structure.

6. The method according to claim 5, wherein vapor-depositing the second layer of superconductive material on the second layer of positive photoresist subjected to reflow comprises:
performing ion beam milling on a coplanar waveguide exposed on the substrate subjected to reflow, and forming a modified photoresist on a surface of the second layer of positive photoresist during ion beam milling, the modified photoresist being in a continuous shape;
vapor-depositing the second layer of superconductive material on the second layer of positive photoresist subjected to ion beam milling; and
performing plasma cleaning on the modified photoresist after the etching the second layer of superconductive material based on the third layer of positive photoresist, to obtain the first substrate structure.

7. The method according to claim 5, further comprising:
performing flood exposure on the positive photoresist on the first substrate structure after the etching the second layer of superconductive material based on the third layer of positive photoresist, to obtain the first substrate structure.

8. The method according to claim 1, wherein preparing the metal column solder joint on the first substrate structure spin-coated with the negative photoresist comprises:
photo-etching a region other than a region corresponding to the metal column solder joint in the negative photoresist, to obtain a second layer of photoresist; and
vapor-depositing a solder joint material on the second layer of photoresist, to obtain the second substrate structure.

9. The method according to claim 8, wherein photo-etching the region other than a region corresponding to the metal column solder joint in the negative photoresist comprises:
exposing the region other than the region corresponding to the metal column solder joint in the negative photoresist; and
developing the negative photoresist subjected to exposure, to obtain the second layer of photoresist.

10. The method according to claim 4, wherein a superconductive material for preparing the UBM layer does not form an alloy with a superconductive metal film layer corresponding to the coplanar waveguide, and does not form an alloy with a solder joint material corresponding to the metal column solder joint.

11. The method according to claim 10, wherein the superconductive material for preparing the UBM layer and the air bridge is niobium (Nb), and the solder joint material for preparing the metal column solder joint is indium (In).

12. An apparatus for preparing a quantum chip, comprising:
a first spin-coating component configured to spin-coat a positive photoresist on a substrate and prepare a UBM layer and an air bridge on the substrate spin-coated with the positive photoresist, so as to obtain a first substrate structure, the first substrate structure having the positive photoresist subjected to photo-etching;
a second spin-coating component configured to spin-coat a negative photoresist on the first substrate structure and prepare a metal column solder joint on the first substrate structure spin-coated with the negative photoresist, so as to obtain a second substrate structure; and
a resist removing component configured to remove the positive photoresist and the negative photoresist from the second substrate structure, so as to obtain a quantum chip comprising the UBM layer, the air bridge, and the metal column solder joint.

13. A mask aligner, comprising a photo-etching component, at least one processor, and a memory, the memory having at least one instruction stored therein, and the at least one instruction, when executed by the at least one processor, causing the photo-etching component to implement the method for preparing a quantum chip according to claim 1.

14. A quantum chip comprising a UBM layer, an air bridge, and a metal column solder joint, the quantum chip being prepared by the method for preparing a quantum chip according to claim 1.

15. A quantum computer, comprising the quantum chip according to claim 14.
